(19) United States
(12) Patent Application Publication
(10) Pub. No.: US 2018/0254180 A1
(43) Pub. Date: Sep. 6, 2018

(54) SUBSTRATE PROCESSING APPARATUS AND SUBSTRATE PROCESSING METHOD

(71) Applicant: Tokyo Electron Limited, Tokyo (JP)

(72) Inventors: Gentaro Goshi, Kumamoto (JP); Keisuke Egashira, Kumamoto (JP); Kento Tsukano, Kumamoto (JP); Hiroshi Marumoto, Kumamoto (JP); Takuro Masuzumi, Kumamoto (JP); Katsuhiro Ookawa, Kumamoto (JP); Hiromi Kiyose, Kumamoto (JP)

(21) Appl. No.: 15/908,967

(22) Filed: Mar. 1, 2018

(30) Foreign Application Priority Data
Mar. 3, 2017 (JP) 2017-040594

(51) Int. Cl. H01L 21/02; H01L 21/67; B08B 3/10

(52) U.S. Cl. CPC H01L 21/02043; H01L 21/0206; H01L 21/6715; B08B 3/10; H01L 21/67051

(57) ABSTRACT

A substrate processing apparatus of an exemplary embodiment includes a liquid processing unit, a detection unit, and a post-processing unit. The liquid processing unit supplies a liquid to a substrate to form a liquid film on the substrate. The detection unit detects the amount of a liquid on the substrate to determine whether the amount of the liquid is acceptable or not. The post-processing unit processes the substrate having the liquid film formed thereon.

### CROSS-REFERENCE TO RELATED APPLICATIONS

This application is based on and claims priority from Japanese Patent Application No. 2017-040594 filed on Mar. 3, 2017 with the Japan Patent Office, the disclosure of which is incorporated herein in its entirety by reference.

### TECHNICAL FIELD

The present disclosure relates to a substrate processing apparatus and a substrate processing method.

### BACKGROUND

Conventionally, there has been known a substrate processing apparatus which forms an anti-drying liquid film on the surface of a substrate, and performs a drying processing by bringing the substrate, having the liquid film formed thereon, into contact with a supercritical fluid (see, e.g., Japanese Patent Laid-Open Publication No. 2013-012538).

### SUMMARY

A substrate processing apparatus according to an aspect of an exemplary embodiment includes a liquid processing unit, a detection unit, and a post-processing unit. The liquid processing unit supplies a liquid to a substrate to form a liquid film on the substrate. The detection unit detects the amount of a liquid on the substrate to determine whether the amount of the liquid is acceptable or not. The post-processing unit processes the substrate having the liquid film formed thereon.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a schematic view illustrating a schematic configuration of a substrate processing system according to an exemplary embodiment.

FIG. 2 is a cross-sectional view illustrating a schematic configuration of a delivery unit.

FIG. 3 is a cross-sectional view illustrating a configuration of a cleaning processing unit.

FIG. 4 is an external perspective view illustrating a configuration of a drying processing unit.

FIG. 5 is a block diagram illustrating a schematic configuration of a control device.

FIG. 6 is a flowchart illustrating a processing procedure of a substrate processing executed by the substrate processing system according to an exemplary embodiment.

FIG. 7 is a schematic view illustrating a schematic configuration of a substrate processing system according to a modification of the exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In a substrate processing apparatus, the amount of a liquid of the liquid film formed on a substrate may be changed in a liquid supply unit, which supplies the liquid to the substrate in order to form the liquid film on the substrate. When the amount of the liquid of the liquid film formed on the substrate is changed, the yield of the substrate after the drying processing may be deteriorated.

An aspect of an embodiment provides a substrate processing apparatus and a substrate processing method, which improve the yield of substrates.

A substrate processing apparatus according to an aspect of an embodiment includes a liquid processing unit, a detection unit, and a post-processing unit. The liquid processing unit supplies a liquid to a substrate to form a liquid film on the substrate. The detection unit detects the amount of a liquid on the substrate to determine whether the amount of the liquid is acceptable or not. The post-processing unit processes the substrate having the liquid film formed thereon.

The above-described apparatus further includes a measurement unit configured to measure at least one of a weight of the substrate having the liquid film formed thereon and a thickness of the liquid film, and the detection unit detects the liquid amount based on a measurement result by the measurement unit.

The above-described apparatus further includes an adjustment unit configured to adjust the liquid amount so that the liquid amount falls within a prescribed range when the detected liquid amount is not within the prescribed range.

The above-described apparatus further includes a placement section on which the substrate carried in from an outside is placed, wherein the placement section includes the adjustment unit.

In the above-described apparatus, the placement section includes the measurement unit.

The above-described apparatus further includes a substrate transport section configured to transfer the substrate. The substrate transport section includes the measurement unit.

In the above-described apparatus, the liquid processing unit includes the measurement unit.

In the above-described apparatus, the post-processing unit brings the substrate having the liquid film formed thereon into contact with a supercritical fluid to dry the substrate.

In the above-described apparatus, the measurement unit measures a weight of the substrate before the liquid film is formed and after a drying processing is performed, and the detection unit detects a dry state of the substrate based on the weight of the substrate after the drying processing is performed.

The above-described apparatus further includes a storage unit configured to store therein the detected liquid amount.

A substrate processing method according to an aspect of an embodiment includes: supplying a liquid to a substrate to form a liquid film on the substrate; detecting an amount of the liquid on the substrate to determine whether the liquid amount is acceptable or not; and processing the substrate having the liquid film formed thereon.

According to an aspect of an embodiment, it is possible to improve the yield of a substrate.

Hereinafter, an embodiment of a substrate processing apparatus and a substrate processing method of the present disclosure will be described in detail with reference to the accompanying drawings. Further, the present disclosure is not limited by the exemplary embodiment described below.

<Outline of Substrate Processing System 1>

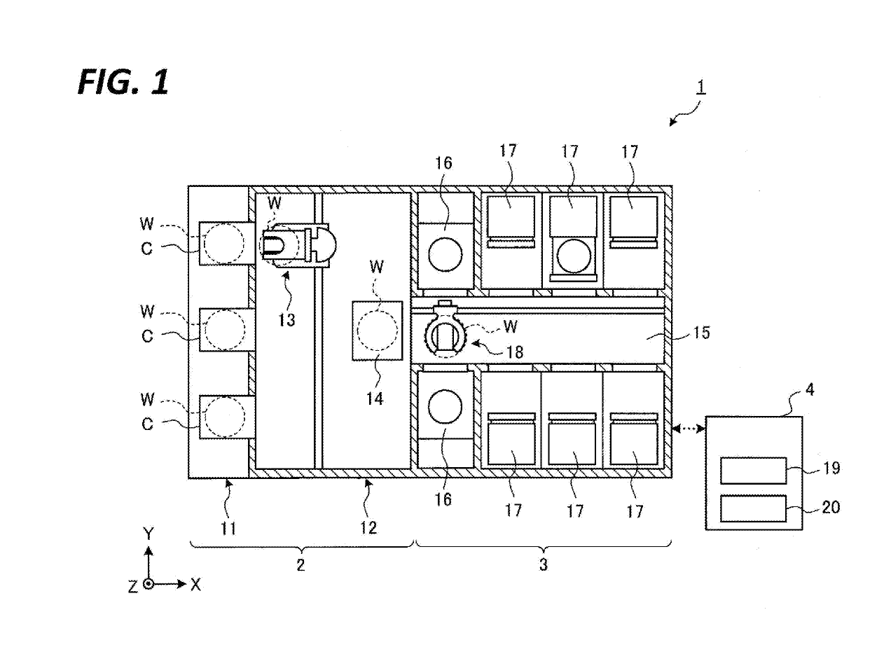

A schematic configuration of a substrate processing system 1 according to an exemplary embodiment will be described with reference to FIG. 1. FIG. 1 is a view illustrating a schematic configuration of the substrate processing system 1 according to the exemplary embodiment. Hereinafter, in order to clarify positional relationships, the X-axis, the Y-axis and the Z-axis, which are orthogonal to each other, will be defined, and the positive Z-axis direction will be regarded as a vertically upward direction.

The substrate processing system 1 includes a carry-in/out station 2 and a processing station 3. The carry-in/out station 2 and the processing station 3 are provided adjacent to each other.

The carry-in/out station 2 includes a carrier placement section 11 and a transport section 12. In the carrier placement section 11, a plurality of carriers C is placed to accommodate therein a plurality of semiconductor wafers W (hereinafter referred to as wafers W) horizontally.

The transport section 12 is provided adjacent to the carrier placement section 11, and includes a substrate transport device 13 and a delivery unit 14. The substrate transport device 13 includes a wafer holding mechanism, which holds the wafer W. Further, the substrate transport device 13 is movable horizontally and vertically and pivotable about a vertical axis, and transfers the wafer W between the carriers C and the delivery unit 14 by using the wafer holding mechanism.

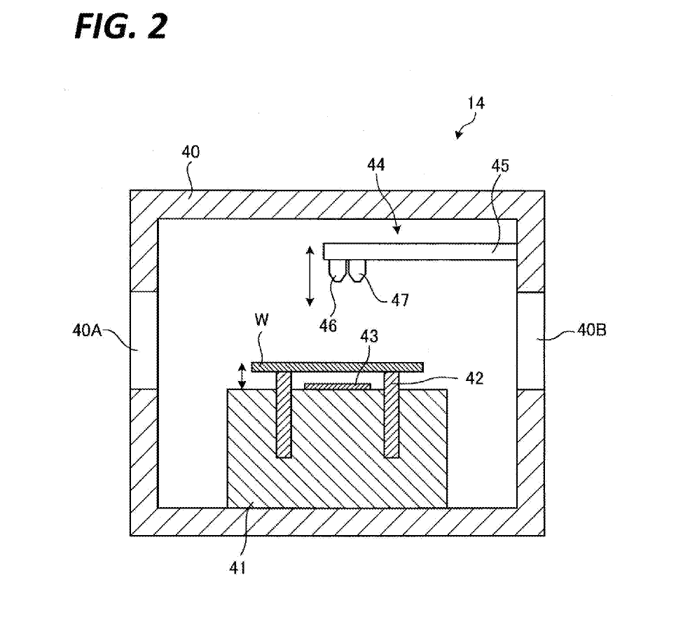

The delivery unit 14 will be described with reference to FIG. 2. FIG. 2 is a cross-sectional view illustrating a schematic configuration of the delivery unit 14.

The delivery unit 14 includes a casing 40, a pedestal 41, a plurality of elevating members 42, a load cell 43, and a liquid-amount adjustment unit 44. The casing 40 is formed with openings 40A and 40B for the carry-in/carry-out of the wafer W by substrate transport devices 13 and 18. The pedestal 41 is disposed in the casing 40. The pedestal 41 is formed with insertion holes, into which the respective elevating members 42 are inserted.

Each elevating member 42 is supported by the pedestal 41 so as to be movable up and down by an elevating drive unit (not illustrated). The elevating member 42 supports the lower surface of the wafer W when the wafer W, carried by the substrate transport device 13 and the substrate transport device 18, is placed on the tip end portion of the elevating member 42. When the elevating member 42 is moved down from a predetermined delivery position by the elevating drive unit in a state of supporting the wafer W thereon, the wafer W is placed on the load cell 43. Further, when the elevating member 42 is moved up by the elevating drive unit in a state where the wafer W is placed on the load cell 43, the elevating member 42 is brought into contact with the lower surface of the wafer W so as to support the wafer W, thereby moving up the wafer W to the delivery position.

The load cell 43 measures the weight of the wafer W, and outputs a signal regarding the weight of the wafer W to a control device 4 to be described later.

The liquid-amount adjustment unit 44 adjusts the amount of an isopropyl alcohol (hereinafter referred to as IPA) liquid, with respect to the wafer W, which is subjected to a cleaning processing by a cleaning processing unit 16 to be described later, and on which IPA in a liquid state is deposited so that a liquid film is formed by the IPA liquid. The liquid-amount adjustment unit 44 includes an arm 45, an IPA supply unit 46, and an IPA suction unit 47.

The arm 45 is supported by the casing 40 so as to be movable up and down by an arm drive unit (not illustrated). The IPA supply unit 46 is attached to the arm 45, and moves up and down together with the arm 45 to supply the IPA liquid to the wafer W. The IPA suction unit 47 is attached to the arm 45, and moves up and down together with the arm 45 to suction the IPA liquid deposited on the surface of the wafer W. The IPA suction unit 47 is, for example, an ejector or a dropper.

Returning to FIG. 1, the processing station 3 is provided adjacent to the transport section 12. The processing station 3 includes a transport section 15, a plurality of cleaning processing units 16, and a plurality of drying processing units 17. The plurality of cleaning processing units 16 and the plurality of drying processing units 17 are arranged on opposite sides of the transport section 15. Further, the arrangement or the number of the cleaning processing units 16 and the drying processing units 17 illustrated in FIG. 1 is merely given by way of example, and is not limited to the illustration.

The transport section 15 includes the substrate transport device 18 therein. The substrate transport device 18 includes a wafer holding mechanism, which holds the wafer W. Further, the substrate transport device 18 is movable horizontally and vertically and pivotable around a vertical axis, and transfers the wafer W between the delivery unit 14 and the cleaning processing units 16 and the drying processing units 17 using the wafer transfer mechanism.

Each cleaning processing unit 16 performs a predetermined cleaning processing on the wafer W transferred by the substrate transport device 18.

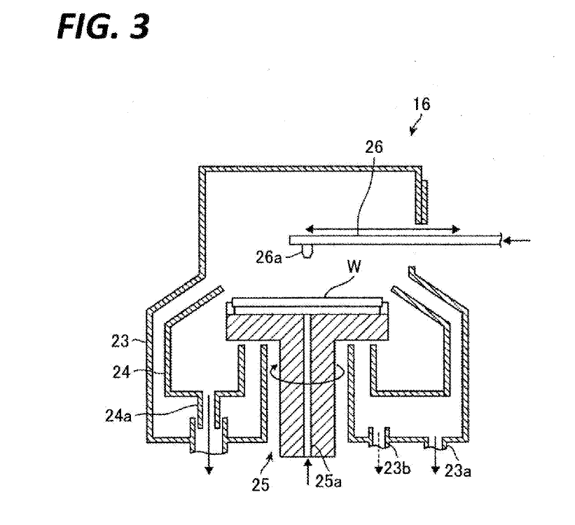

The cleaning processing unit 16 will be described with reference to FIG. 3. FIG. 3 is a cross-sectional view illustrating a configuration of the cleaning processing unit 16. The cleaning processing unit 16 is, for example, configured as a single-wafer-type cleaning processing unit, which cleans the wafers W one by one by spin cleaning.

The cleaning processing unit 16 holds the wafer W substantially horizontally by a wafer holding mechanism 25, which is disposed in an outer chamber 23, which defines a processing space therein, and rotates the wafer W by rotating the wafer holding mechanism 25 around a vertical axis. Then, the cleaning processing unit 16 performs a cleaning processing on the surface of the wafer W by causing a nozzle arm 26 to be located above the rotating wafer W, and supplying a chemical liquid or a rinse liquid in a predetermined order from a chemical liquid nozzle 26a, which is provided on the tip end portion of the nozzle arm 26.

Further, in the cleaning processing unit 16, a chemical liquid supply path 25a is also formed inside the wafer holding mechanism 25. Then, the back surface of the wafer W is cleaned by a chemical liquid or a rinse liquid supplied from the chemical liquid supply path 25a.

In the above-described cleaning processing of the wafer W, for example, particles or organic pollutants are first removed by an SC1 liquid (a mixture liquid of ammonia and hydrogen peroxide), which is an alkaline chemical liquid, and then rinse cleaning is performed by deionized water (hereinafter referred to as “DIW”), which is a rinse liquid. Next, a natural oxide film is removed by an aqueous diluted hydrofluoric acid liquid (hereinafter referred to as “DHF”), which is an acid chemical liquid, and then rinse cleaning is performed by DIW.

The aforementioned various chemical liquids are received by the outer chamber 23 or an inner cup 24 disposed in the outer chamber 23, and are discharged from a liquid discharge port 23a, which is provided in the bottom of the outer chamber 23, or a liquid discharge port 24a, which is provided in the bottom of the inner cup 24. Further, the atmosphere in the outer chamber 23 is evacuated from a gas discharge port 23b, which is provided in the bottom of the outer chamber 23.

After the rinse processing of the wafer W described above, while rotating the wafer holding mechanism 25, the IPA liquid is supplied to the front surface and the back surface of the wafer W so as to be replaced with the DIW remaining on opposite surfaces of the wafer W. Thereafter, the rotation of the wafer holding mechanism 25 is gently stopped.

The wafer W, which has been completely cleaned as described above, is formed with a liquid film of the IPA liquid on the surface thereof. Further, the thickness δ of the liquid film may be calculated as represented in Equation (1).

$$\begin{matrix}Equation 1 & \\ δ = {( \frac{3 Qv}{2 π {r}^{2} {ω}^{2 }} )}^{1 / 3} & ( 1 )\end{matrix}$$

Here, “Q” is the discharge flow rate, “ν” is the kinematic viscosity, “ω” is the rotational speed, and “r” is the radius of the wafer W.

The wafer W, having the liquid film formed thereon, is delivered to the substrate transport device 18 by an exchange mechanism (not illustrated) provided in the wafer holding mechanism 25, and is carried out from the cleaning processing unit 16.

The liquid film, formed on the surface of the wafer W, functions as an anti-drying liquid, which prevents pattern collapse from occurring due to evaporation (vaporization) of the liquid on the surface of the wafer W during the transfer of the wafer W from the cleaning processing unit 16 to the drying processing unit 17 or during the carry-in of the wafer W to the drying processing unit 17.

Returning to FIG. 1, the drying processing unit 17 performs a drying processing on the wafer W, which has been cleaned by the cleaning processing unit 16, using a supercritical fluid. In the drying processing, by bringing the supercritical fluid of CO2 into contact with the IPA liquid on the wafer W, the IPA liquid is dissolved in and removed by the supercritical fluid. Thereby, the wafer W is dried.

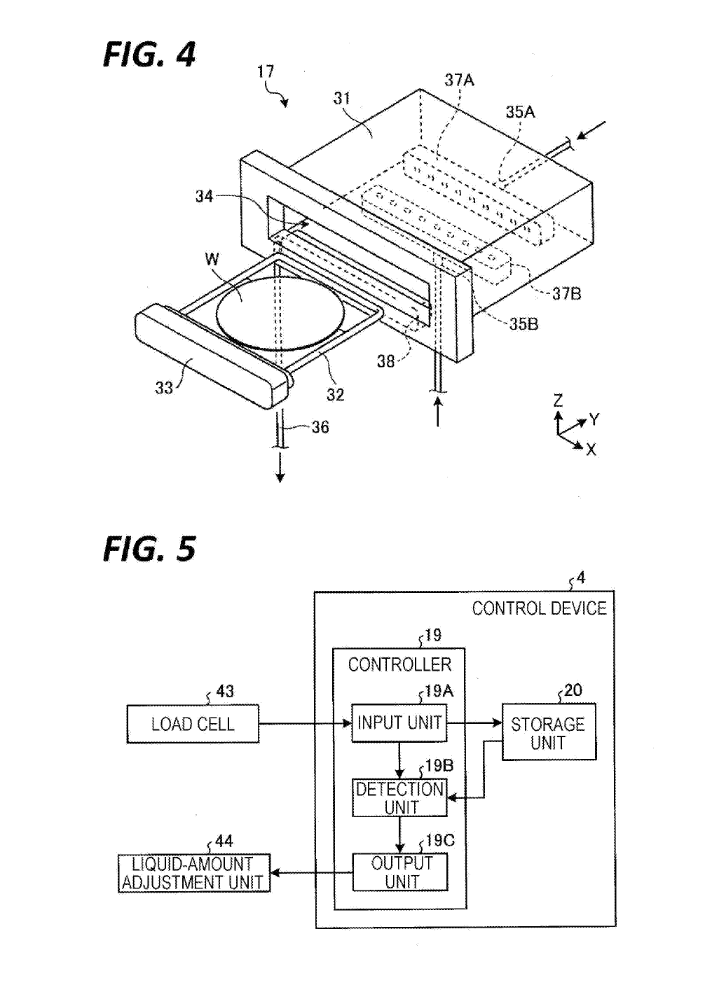

The drying processing unit 17 will be described with reference to FIG. 4. FIG. 4 is an external perspective view illustrating a configuration of the drying processing unit 17.

The drying processing unit 17 includes a main body 31, a holding plate 32, and a lid member 33. An opening 34 for the carry-in/carry-out of the wafer W is formed in the main body 31 having a casing shape. The holding plate 32 holds the wafer W, which is a processing target, horizontally. The lid member 33 supports the holding plate 32, and hermetically seals the opening 34 when the wafer W is carried into the main body 31.

The main body 31 is a container in which a processing space capable of accommodating therein the wafer W therein is formed, and supply ports 35A and 35B and a discharge port 36 are provided in the wall portion of the main body 31. The supply ports 35A and 35B and the discharge port 36 are respectively connected to supply lines for circulating a supercritical fluid, which are provided on the upstream side and the downstream side of the drying processing unit 17.

The supply port 35A is connected to the side surface of the casing-shaped main body 31 opposite to the opening 34. Further, the supply port 35B is connected to the bottom surface of the main body 31. Further, the discharge port 36 is connected to the lower side of the opening 34. Further, although FIG. 4 illustrates two supply ports 35A and 35B and one discharge port 36, the number of the supply ports 35A and 35B and the discharge port 36 is not particularly limited.

Further, inside the main body 31, fluid supply headers 37A and 37B and a fluid discharge header 38 are provided. All of the fluid supply headers 37A and 37B and the fluid discharge header 38 are formed with a large number of holes.

The fluid supply header 37A is connected to the supply port 35A, and is provided adjacent to the side surface opposite to the opening 34 inside the casing-shaped main body 31. Further, a large number of holes formed in the fluid supply header 37A face the opening 34 side.

The fluid supply header 37B is connected to the supply port 35B, and is provided in the central portion of the bottom surface inside the casing-shaped main body 31. Further, a large number of holes formed in the fluid supply header 37B face upward.

The fluid discharge header 38 is connected to the discharge port 36, is adjacent to the side surface on the opening 34 side inside the casing-shaped main body 31, and is provided below the opening 34. Further, a large number of openings formed in the fluid discharge header 38 face the fluid supply header 37A side.

The fluid supply headers 37A and 37B supply the supercritical fluid into the main body 31. Further, the fluid discharge header 38 guides the supercritical fluid inside the main body 31 to the outside of the main body 31 so as to discharge the supercritical fluid. Further, the supercritical fluid discharged to the outside of the main body 31 via the fluid discharge header 38 includes the IPA liquid dissolved from the surface of the wafer W into the supercritical fluid.

The drying processing unit 17 further includes a pressing mechanism (not illustrated). The pressing mechanism functions to press the lid member 33 toward the main body 31 against an internal pressure, which is generated by the supercritical fluid, in the supercritical state, supplied into the processing space inside the main body 31, thereby hermetically sealing the processing space. Further, for example, a heat insulating material or a tape heater may be provided on the surface of the main body 31 so that the supercritical fluid supplied into the processing space may maintain a predetermined temperature.

Returning to FIG. 1, the substrate processing system 1 includes the control device 4. The control device 4 is, for example, a computer, and includes a controller 19 and a storage unit 20. Here, the control device 4 will be described with reference to FIG. 5. FIG. 5 is a block diagram showing a schematic configuration of the control device 4.

The storage unit 20 is realized by a semiconductor memory device such as, for example, a random access memory (RAM) or a flash memory, or a storage device such as a hard disk or an optical disk.

The controller 19 includes a microcomputer having, for example, a central processing unit (CPU), a read only memory (ROM), RAM, and input/output ports, or various circuits. The CPU of such a microcomputer realizes control of, for example, the substrate transport devices 13 and 18, the cleaning processing unit 16, the drying processing unit 17, and the liquid-amount adjustment unit 44 by reading out and executing a program stored in the ROM.

Further, such a program is recorded in a computer readable recording medium, and may be installed in the storage unit 20 of the control device 4 from the recording medium. Examples of the computer readable recording medium include a hard disk (HD), a flexible disk (FD), a compact disk (CD), a magneto optical disk (MO), and a memory card.

The controller 19 includes an input unit 19A, a detection unit 19B, and an output unit 19C.

A signal regarding the weight of the wafer W, which is measured by the load cell 43, is input to the input unit 19A. Signals regarding the weight of the wafer W before the cleaning processing, that is, the weight of the wafer W having no liquid film formed thereon, the weight of the wafer W after the cleaning processing, that is, the weight of the wafer W having the liquid film formed thereon, and the weight of the wafer W after the drying processing are input to the input unit 19A. A signal regarding the weight of the wafer W after the cleaning processing is stored in the storage unit 20 as data regarding the weight of the wafer W after the cleaning processing.

The detection unit 19B detects the weight of the wafer W before and after the cleaning processing and the weight of the wafer W after the drying processing based on the signals input to the input unit 19A.

Specifically, the detection unit 19B detects the amount of the IPA liquid on the wafer W (hereinafter referred to as “the amount of the IPA liquid) by subtracting the weight of the wafer W before the cleaning processing from the weight of the wafer W after the cleaning processing. Further, the detection unit 19B detects the residual amount of the IPA liquid on the wafer W by subtracting the weight of the wafer W before the cleaning processing from the weight of the wafer W after the drying processing.

The detection unit 19B determines that the amount of the IPA liquid is normal when the amount of the IPA liquid is within a prescribed range, and determines that the amount of the IPA liquid is abnormal when the amount of the IPA liquid is out of the prescribed range. The prescribed range is a preset range, within which the amount of the IPA liquid is equal to or greater than a predetermined lower limit value, and is also equal to or less than a predetermined upper limit value.

The predetermined lower limit value is a preset value, and is the liquid amount, which may prevent pattern collapse from occurring due to evaporation (vaporization) of the liquid on the surface of the wafer W during the transfer of the wafer W to the drying processing unit 17 or during the carry-in of the wafer W to the drying processing unit 17. The predetermined upper limit value is a preset value, and is the liquid amount, which prevents a large number of particles from adhering to the wafer W after the drying processing.

Further, the detection unit 19B determines that the wafer W is dried when the residual amount of the IPA liquid on the wafer W is equal to or less than a predetermined value, and determines that the wafer W is not dried when the residual amount of the IPA liquid on the wafer W is greater than the predetermined value. The predetermined value is a preset value. That is, the detection unit 19B detects the dry state of the wafer W by the drying processing.

When it is determined that the amount of the IPA liquid is abnormal, the output unit 19C outputs a signal regarding the amount of the IPA liquid to the liquid-amount adjustment unit 44, and causes the liquid-amount adjustment unit 44 to adjust the flow rate of the IPA liquid.

Thereby, the liquid-amount adjustment unit 44 adjusts the amount of the IPA liquid on the wafer W so that the amount of the IPA liquid is within a prescribed range. Specifically, when the amount of the IPA liquid is less than the predetermined lower limit value, the IPA supply unit 46 supplies the IPA liquid to the wafer W. Further, when the amount of the IPA liquid is greater than the predetermined upper limit value, the IPA suction unit 47 suctions the IPA liquid from the wafer W.

Further, when it is determined that the wafer W is not dried, the output unit 19C outputs a signal to carry the wafer W again into the drying processing unit 17 and perform a drying processing, so as to dry the wafer W.

<Substrate Processing>

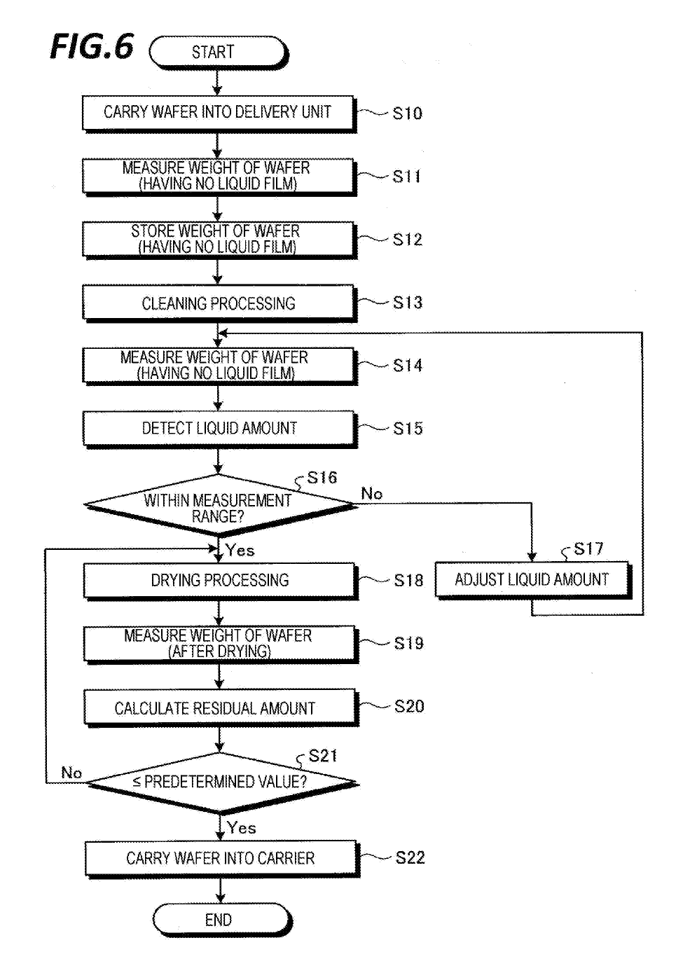

Next, a substrate processing in the substrate processing system 1 will be described with reference to FIG. 6. FIG. 6 is a flowchart illustrating a processing procedure of a substrate processing executed by the substrate processing system 1 according to the present exemplary embodiment.

The substrate processing system 1 carries the wafer W from the carrier C to the delivery unit 14 by the substrate transport device 13 (S10), measures the weight of the wafer W having no liquid film formed thereon (S11), and stores the measured weight in the storage unit 20 (S12).

In the substrate processing system 1, the wafer W is carried out from the delivery unit 14, and is carried into the cleaning processing unit 16 by the substrate transport device 18, so that a cleaning processing is performed on the wafer W (S13). Thereby, a liquid film is formed on the wafer W.

When the cleaning processing ends, the substrate processing system 1 transfers the wafer W from the cleaning processing unit 16 to the delivery unit 14 by the substrate transport device 18, and measures the weight of the wafer W having the liquid film formed thereon (S14).

The substrate processing system 1 detects the amount of the IPA liquid by subtracting the weight of the wafer W having no liquid film formed thereon from the weight of the wafer W having the liquid film formed thereon (S15).

When the amount of the IPA liquid is out of the prescribed range (S16: No), the substrate processing system 1 causes the liquid-amount adjustment unit 44 to adjust the amount of the IPA liquid so that the amount of the IPA liquid falls within the prescribed range (S17).

When the amount of the IPA liquid is within the prescribed range (S16: Yes), the substrate processing system 1 transfers the wafer W from the delivery unit 14 to the drying processing unit 17 by the substrate transport device 18 to perform a drying processing (S18).

When the drying processing ends, the substrate processing system 1 transfers the wafer W from the drying processing unit 17 to the delivery unit 14 by the substrate transport device 18, and measures the weight of the wafer W after the drying processing (S19).

The substrate processing system 1 calculates the residual amount of the IPA liquid by subtracting the weight of the wafer W having no liquid film formed thereon from the weight of the wafer W after the drying processing (S20).

When the residual amount of the IPA liquid is greater than a predetermined value (S21: No), the substrate processing system 1 again carries the wafer W into the drying processing unit 17 to again perform the drying processing.

When the residual amount of the IPA liquid is equal to or less than the predetermined value (S21: Yes), the substrate processing system 1 carries out the wafer W from the delivery unit 14 by the substrate transport device 13, and carries the wafer W into the carrier C (S22).

### Effects of Exemplary Embodiment

Next, effects of the present exemplary embodiment will be described.

When a liquid film of an IPA liquid is formed on the wafer W by the cleaning processing unit 16, the amount of the IPA liquid may be different in each cleaning processing unit 16 in some cases. Further, the amount of the IPA liquid may be changed due to aged deterioration.

It has been found that, when the wafer W in which the amount of the IPA liquid is greater than a predetermined upper limit value is subjected to a drying processing, a large number of particles adhere to the wafer W after the drying processing. Further, when the amount of the IPA liquid is less than a predetermined lower limit value, there is a risk of pattern collapse occurring, for example, during the transport of the wafer W.

The substrate processing system 1 detects the amount of the IPA liquid on the wafer W, which is subjected to a cleaning processing and on which the liquid film of the IPA liquid is formed. Thereby, it is possible to manage the amount of the IPA liquid for each wafer W. Therefore, by drying the wafer W in which a detected amount of the IPA liquid is within a prescribed range, it is possible to reduce particles adhering to the wafer W, and to prevent pattern collapse, thereby improving the yield of the wafer W.

The substrate processing system 1 measures the weight of the wafer W before and after the cleaning processing, and detects the amount of the IPA liquid by subtracting the weight of the wafer W before the cleaning processing from the weight of the wafer W after the cleaning processing. Thereby, it is possible to accurately detect the amount of the IPA liquid.

When the amount of the IPA liquid is out of a prescribed range, the substrate processing system 1 adjusts the amount of the IPA liquid by the liquid-amount adjustment unit 44 so that the amount of the IPA liquid falls within the prescribed range. Thereby, it is possible to prevent the wafer W in which the amount of the IPA liquid is out of the prescribed range from being carried into the drying processing unit 17.

For example, when the amount of the IPA liquid is greater than a predetermined upper limit value, the amount of the IPA liquid is reduced by the IPA suction unit 47, and when the amount of the IPA liquid is less than a predetermined lower limit value, the amount of the IPA liquid Is increased by the IPA supply unit 46, whereby the wafer W in which the amount of the IPA liquid has fallen within the prescribed range may be carried into the drying processing unit 17 so that the drying processing is performed on the wafer W. Therefore, it is possible to improve the yield of the wafer W.

In the substrate processing system 1, the liquid-amount adjustment unit 44 is provided in the delivery unit 14. Thereby, the delivery unit 14 may be disposed in the space in which an existing delivery unit is provided, which may prevent an increase in the size of the substrate processing system 1 while improving the yield of the wafer W.

In the substrate processing system 1, the load cell 43 is provided in the delivery unit 14. Thereby, the weight of the wafer W may be measured when delivering the wafer W from the carry-in/carry-out station 2 to the processing station 3, which may prevent an increase in the processing time of the wafer W. Further, the delivery unit 14 may be disposed in the space where an existing delivery unit is provided, which may prevent an increase in the size of the substrate processing system 1 while improving the yield of the wafer W.

The substrate processing system 1 detects the residual amount of the IPA liquid on the wafer W based on a difference between the weight of the wafer W after the drying processing and the weight of the wafer W before the cleaning processing. Thereby, it is possible to detect the dry state of the wafer W.

### Modification of Exemplary Embodiment

Next, a modification of the above-described exemplary embodiment will be described.

In the above-described exemplary embodiment, the weight of the wafer W before and after the cleaning processing and the weight of the wafer W after the drying processing are measured by the load cell 43 provided in the delivery unit 14, but the present disclosure is not limited thereto, and the load cell 43 may be provided in a constituent member other than the delivery unit 14 to measure the weight of the wafer W.

For example, the load cell 43 may be provided in, for example, an arm (not illustrated), which delivers the wafer W between the drying processing unit 17 and the substrate transport device 18, the substrate transport device 18, or the cleaning processing unit 16. Thereby, since it is possible to measure the weight of the wafer W during the transport of the wafer W or during the cleaning processing, a processing of measuring the weight of the wafer W by the delivery unit 14 may be omitted. Therefore, it is possible to prevent an increase in the processing time of the wafer W. Further, a plurality of load cells 43 may be provided in, for example, the delivery unit 14 or the substrate transport device 18.

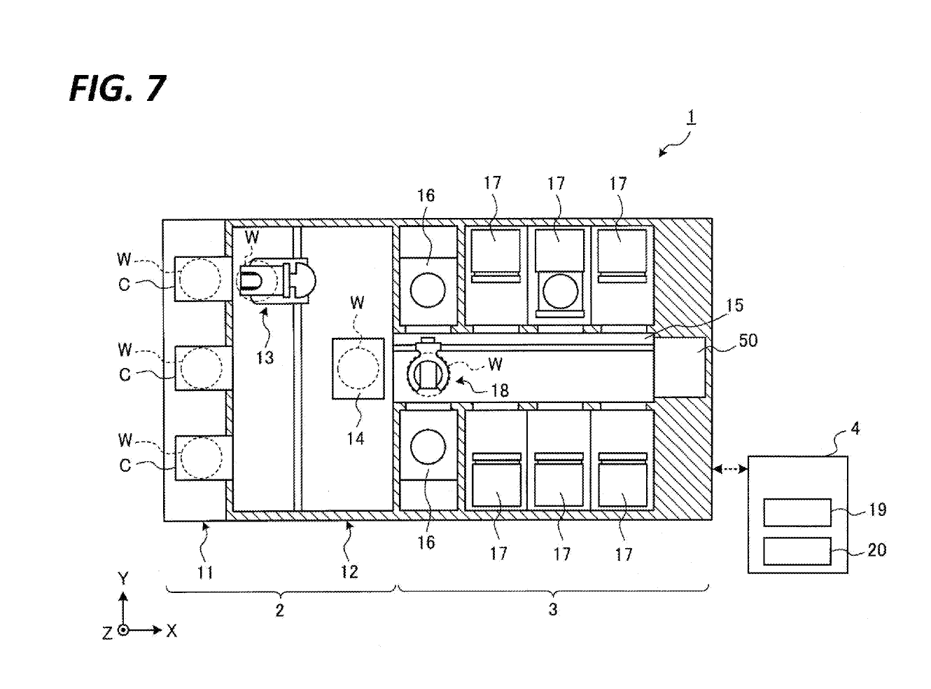

Further, the liquid amount adjustment unit 44 may be provided in a member other than the delivery unit 14. For example, an adjustment unit 50 having the load cell 43 and the liquid amount adjustment unit 44 may be separately provided in the substrate processing system 1 as illustrated in FIG. 7. FIG. 7 is a schematic view illustrating a schematic configuration of the substrate processing system 1 according to a modification of the present exemplary embodiment.

For example, the weight of the wafer W before the cleaning processing and after the drying processing may be measured by the delivery unit 14, and the weight of the wafer W having the liquid film of the IPA liquid formed thereon by the cleaning processing may be measured by the adjustment unit 50, so that the amount of the IPA liquid is adjusted. Thereby, it is possible to prevent the IPA liquid from adhering to the elevating members 42 of the delivery unit 14, thereby preventing the IPA liquid adhered to the elevating members 42 from adhering to the wafer W after the drying processing. Further, the weight of the wafer W before and after the cleaning processing and the drying processing may be measured by the adjustment unit 50.

Further, the adjustment unit 50 may be provided, for example, in the upper portion of the main body 31 of the drying processing unit 17. Thereby, the time taken to transport the wafer W from the adjustment unit 50 to the drying processing unit 17 may be reduced, which may prevent an increase in the processing time of the wafer W.

Further, for example, the substrate processing system 1 may adjust, for example, the amount of the IPA liquid by measuring the weight of the wafer W for every predetermined number of sheets or for every predetermined period of time. In this case, when the amount of the IPA liquid is out of a prescribed range, the output unit 19C outputs a signal to the cleaning processing unit 16 so that the amount of the IPA liquid falls within the prescribed range by changing parameters in the cleaning processing unit 16, for example, the discharge flow rate Q of the IPA liquid or the rotational speed ω based on the detected amount of the IPA liquid. Thereby, it is possible to reduce the processing time of the wafer W while improving the yield of the wafer W by preventing the wafer W in which the amount of the IPA liquid is out of the prescribed range from being carried into the drying processing unit 17.

Further, a warning that the amount of the IPA liquid is out of the prescribed range may be issued without adjustment of the amount of the IPA liquid by the liquid-amount adjustment unit 44. Further, a warning may be issued together with the adjustment by the liquid-amount adjustment unit 44. The warning is issued, for example, by displaying a warning on a monitor, turning on a warning lamp, or generating a warning sound. Thereby, that the amount of the IPA liquid is out of the prescribed range is notified to the worker to allow the worker to change the parameters in the cleaning processing unit 16, for example, the discharge flow rate Q of the IPA liquid or the rotational speed ω.

Further, the substrate processing system 1 may measure the amount of the IPA liquid by comparing the state of the wafer W after the liquid film is formed thereon, for example, the weight of the wafer W after the liquid film is formed thereon with a preset first predetermined weight. Further, the substrate processing system 1 may measure the residual amount of the IPA liquid by comparing the state of the wafer W after the drying processing, for example, the weight of the wafer W after the drying processing with a preset second predetermined weight.

Further, the liquid amount of the IPA liquid or the residual amount of the IPA liquid may be stored in the storage unit 20. Thereby, it is possible to accumulate changes in the amount of IPA liquid or the residual amount of the IPA liquid and analyze these amounts using the accumulated data.

Further, the amount of the IPA liquid may be detected by measuring the thickness δ of the liquid film of the wafer W having the liquid film formed thereon.

Further, when the amount of the IPA liquid is greater than a predetermined upper limit value, the liquid-amount adjustment unit 44 may adjust the amount of the IPA liquid so as to fall within the prescribed range by volatilizing the IPA liquid. The liquid-amount adjustment unit 44 performs adjustment, for example, by heating and volatilizing the IPA liquid using a heating device (not illustrated). Further, the amount of the IPA liquid may be adjusted by spontaneous volatilization. Further, the liquid-amount adjustment unit 44 may adjust the amount of the IPA liquid by rotating the wafer W having the liquid film formed thereon.

Further, when the amount of the IPA liquid is out of the prescribed range, the substrate processing system 1 may perform the cleaning processing again so that the amount of the IPA liquid falls within the prescribed range.

Further, in the above-described exemplary embodiment, the substrate processing of forming the liquid film of the IPA liquid on the wafer W and drying the wafer W using the supercritical fluid has been described, but the present disclosure is not limited thereto. The present disclosure may be appropriately used in a substrate processing of forming a liquid film on the wafer W, and thereafter performing a drying processing, solidification of the liquid film, or any other processing.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate processing apparatus comprising:
a liquid processing unit configured to supply a liquid to a substrate so as to form a liquid film on the substrate;
a detection unit configured to detect an amount of the liquid on the substrate so as to determine whether the liquid amount is acceptable or not; and
a post-processing unit configured to process the substrate having the liquid film formed thereon.

2. The substrate processing apparatus of claim 1, further comprising a measurement unit configured to measure at least one of a weight of the substrate having the liquid film formed thereon and a thickness of the liquid film,
wherein the detection unit detects the liquid amount based on a measurement result by the measurement unit.

3. The substrate processing apparatus of claim 2, further comprising an adjustment unit configured to adjust the liquid amount such that the liquid amount falls within a prescribed range when the detected liquid amount is not within the prescribed range.

4. The substrate processing apparatus of claim 3, further comprising a placement section on which the substrate carried in from an outside is placed,
wherein the placement section includes the adjustment unit.

5. The substrate processing apparatus of claim 4, wherein the placement section includes the measurement unit.

6. The substrate processing apparatus of claim 2, further comprising a substrate transport section configured to transport the substrate therein,
wherein the substrate transport section includes the measurement unit.

7. The substrate processing apparatus of claim 2, wherein the liquid processing unit includes the measurement unit.

8. The substrate processing apparatus of claim 2, wherein the post-processing unit brings the substrate having the liquid film formed thereon into contact with a supercritical fluid so as to dry the substrate.

9. The substrate processing apparatus of claim 8, wherein the measurement unit measures a weight of the substrate before the liquid film is formed and after a drying processing is performed, and
the detection unit detects a dry state of the substrate based on the weight of the substrate after the drying processing is performed.

10. The substrate processing apparatus of claim 1, further comprising a storage unit configured to store therein the detected liquid amount.

11. A substrate processing method comprising:
supplying a liquid to a substrate so as to form a liquid film on the substrate;
detecting an amount of the liquid on the substrate so as to determine whether the liquid amount is acceptable or not; and
processing the substrate having the liquid film formed thereon.
